(19) United States
(12) Patent Application Publication
(10) Pub. No.: US 2007/0103057 A1
(43) Pub. Date: May 10, 2007

(54) Yellow phosphor and white light emitting device incorporating the same

(75) Inventors: Jong Rak Sohn, Suwon (KR); Mihail Nazarov, Suwon (KR); Chul Soo Yoon, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/585,214

(22) Filed: Oct. 24, 2006

(30) Foreign Application Priority Data
Nov. 4, 2005 (KR) 10-2005-0105378

(51) Int. Cl. H01L 33/00

(52) U.S. Cl. 313/503; 313/512

(57) ABSTRACT

The invention relates to yellow phosphor with a red wavelength region thereof reinforced and a white light emitting device incorporating the same. The yellow phosphor has a formula of Mₓ(Al, Ga)₅O₁₂:Ce_{y},Eu_{z}, in which M is at least one selected from a group consisting of Tb, Y, Gd, La and Sm, where 2.4≦x≦2.998, 0.001≦y≦0.3 and 0.001≦z≦0.3.

### CLAIM OF PRIORITY

This application claims the benefit of Korean Patent Application No. 2005-105378 filed on Nov. 4, 2005, in the Korean Intellectual Property Office, the disclosure of which is incorporated herein by reference.

### BACKGROUND OF THE INVENTION

1. Field of the Invention

The present invention relates to yellow phosphor and a white light emitting device incorporating the same, and more particularly, to yellow phosphor which is reinforced in red wavelength region thereof to realize superior color rendering index and color reproducibility, and a white light emitting device incorporating the same.

2. Description of the Related Art

Recently, light emitting diodes (LEDs) have attracted attention as backlights of LCD displays and as next-generation light sources for illumination. More particularly, researches have been focused on white light emitting devices which include the LEDs. In order to realize a high-quality, high-efficiency white light emitting device, researches are under way on various phosphors as well as the structure of the LED itself.

The most widely used method for realizing a white light emitting device using an LED is to apply yellow phosphor on a blue LED. For the yellow phosphor, YAG:Ce, TAG:Ce and silicate phosphor are mainly used. In particular, YAG:Ce or TAG:Ce is high quality phosphor utilizing the light emission characteristics of Ce and uses blue light as excitation light. However, such conventional yellow phosphor has a simple spectrum of a yellow light emission region, thus requiring reinforcement of a red wavelength region thereof.

FIG. 1 is a graph illustrating a light emission spectrum of conventional yellow phosphor, particularly TAG:Ce phosphor. Referring to FIG. 1, the conventional TAG:Ce phosphor exhibits weak light emission intensity especially in the red wavelength region of 600 nm or higher. Therefore, in order to obtain a superior color rendering index using the blue LED chip and yellow phosphor made of TAG:Ce, the red wavelength region needs to be reinforced.

In an effort to reinforce the weak red wavelength region, researches have been conducted on adding red phosphor to the yellow phosphor. However, using two kinds of phosphors cause degradation of light emission characteristics. In addition, having different densities, the two kinds of phosphors are dispersed in a resin unevenly. Therefore, the yellow phosphor needs to be sufficiently reinforced in its red wavelength region.

### SUMMARY OF THE INVENTION

The present invention has been made to solve the foregoing problems of the prior art and therefore an object of certain embodiments of the present invention is to provide yellow phosphor with a red wavelength region thereof reinforced to realize a superior color rendering index.

Another object of certain embodiments of the invention is to provide a white light emitting device which includes the yellow phosphor to realize a superior color rendering index and color reproducibility.

According to an aspect of the invention for realizing the object, there is provided yellow phosphor having a composition expressed by a formula Mₓ(Al, Ga)₅O₁₂:Ce_{y},Eu_{z}, wherein M is at least one selected from a group consisting of Tb, Y, Gd, La and Sm, where 2.4≦x≦2.998, 0.001≦y≦0.3 and 0.001≦z≦0.3.

According to an embodiment of the present invention, the yellow phosphor has a composition expressed by a formula TAG:Ce,Eu (Tb_{3-y-}zAl₅O₁₂:Ce_{y},Eu_{z}). In this case, the content of Ce in the phosphor may be 1 to 10 mol % (i.e., 0.10≦y≦0.1). In addition, in a case where the content of Ce is 1 to 10 mol % in the phosphor, the content of Eu may be 1 to 10 mol % (i.e., 0.01≦z≦0.1). In another embodiment, the phosphor may have a formula of YAG:Ce,Eu (Y_{3-y-z}Al₅O₁₂:Ce_{y},Eu_{z}).

According to the present invention, Eu acts as a co-activator for reinforcing the red wavelength region of the phosphor. As the content of Eu in the phosphor increases, the effect of reinforcement of the red wavelength region due to Eu becomes relatively greater. On the other hand, as the content of Ce is greater in the phosphor, the effect of reinforcement of the red wavelength region due to Eu becomes relatively smaller. Therefore, the contents of Ce and Eu in the phosphor can be suitably adjusted to sufficiently reinforce the red wavelength region.

According to another aspect of the invention for realizing the object, there is provided a light emitting device including a blue light source; and yellow phosphor dispersed on the blue light source, wherein the yellow phosphor has a composition expressed by a formula, Mₓ(Al, Ga)₅O₁₂:Ce_{y},Eu_{z}, and M is at least one selected from a group consisting of Tb, Y, Gd, La and Sm, where 2.4≦x≦2.998, 0.001≦y≦0.3 and 0.001≦z≦0.3.

According to an embodiment of the present invention, the yellow phosphor in the white light emitting device has a formula of TAG:Ce,Eu. In another embodiment, the yellow phosphor in the white light emitting device may have a formula of YAG:Ce,Eu.

According to a preferred embodiment of the present invention, the blue light source is a blue LED. In this case, the blue LED may have a peak light emission wavelength of 420 to 480 nm. The white light emitting device may further include an encapsulant formed on the blue LED and the encapsulant may have the yellow phosphor dispersed therein. The encapsulant may be made of an epoxy resin, silicone resin or hybrid resin of epoxy and silicone. As an alternative, a different kind of blue light source such as a blue light emission lamp can be used instead of the blue LED.

According to the present invention, the conventionally weak red wavelength region can be reinforced by the yellow phosphor itself. Thereby, only the yellow phosphor without using red phosphor can be used to realize a white light emitting device having a superior color rendering index and color reproducibility.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a graph showing the light emission spectrum of conventional yellow phosphor;

FIGS. 2 to 5 are graphs showing the light emission spectra of yellow phosphors according to embodiments of the present invention;

FIGS. 6 to 9 are graphs showing the light emission spectra of yellow phosphors according to other embodiments of the present invention;

FIGS. 10 to 13 are graphs showing the light emission spectra of yellow phosphors according to further other embodiments of the present invention;

FIG. 14 is a graph showing the relative light emission intensity of TAG:Ce,Eu phosphor with respect to the light emission intensity of TAG:Ce phosphor;

FIG. 15 is a graph showing the light emission spectrum of a light emitting device using yellow phosphor according to an embodiment of the present invention; and

FIG. 16 is a sectional view illustrating a light emitting device according to an embodiment of the present invention.

### DETAILED DESCRIPTION OF THE PREFERRED EMBODIMENT

The present invention now will be described more fully hereinafter with reference to the accompanying drawings, in which preferred embodiments of the invention are shown. The embodiments described hereunder are only illustrative, and variations and modifications are possible within the scope of the invention.

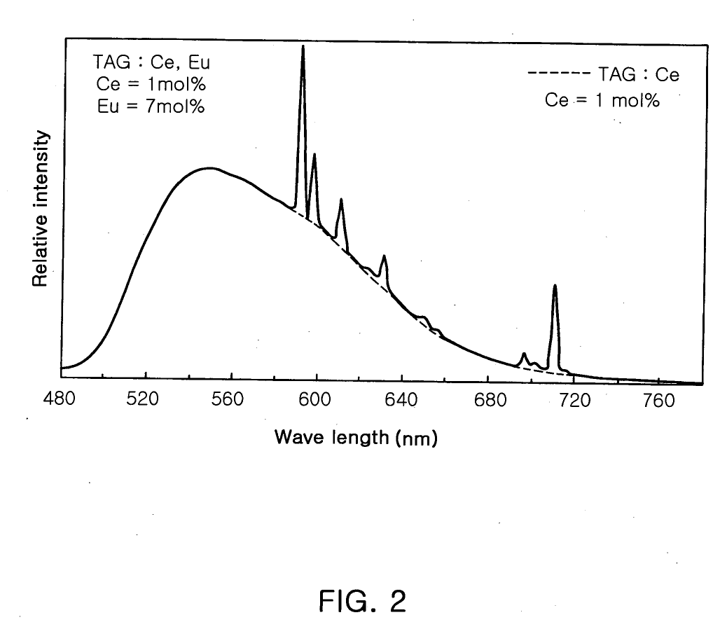

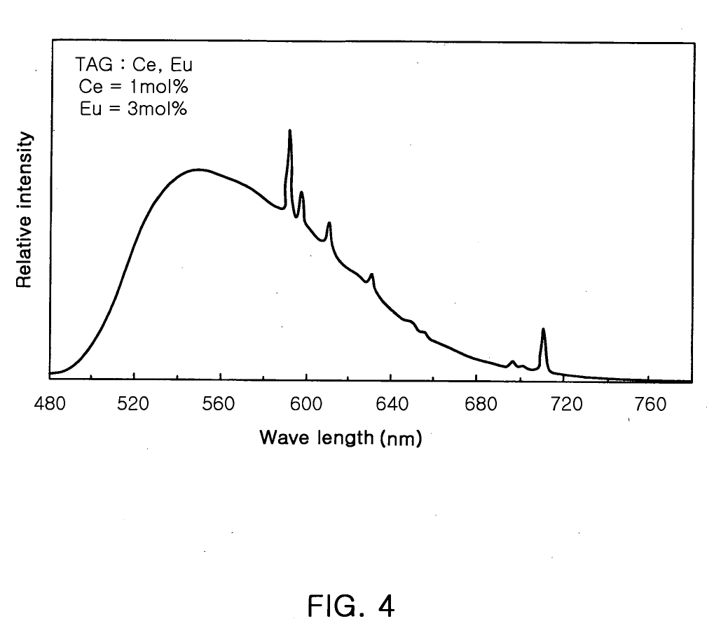

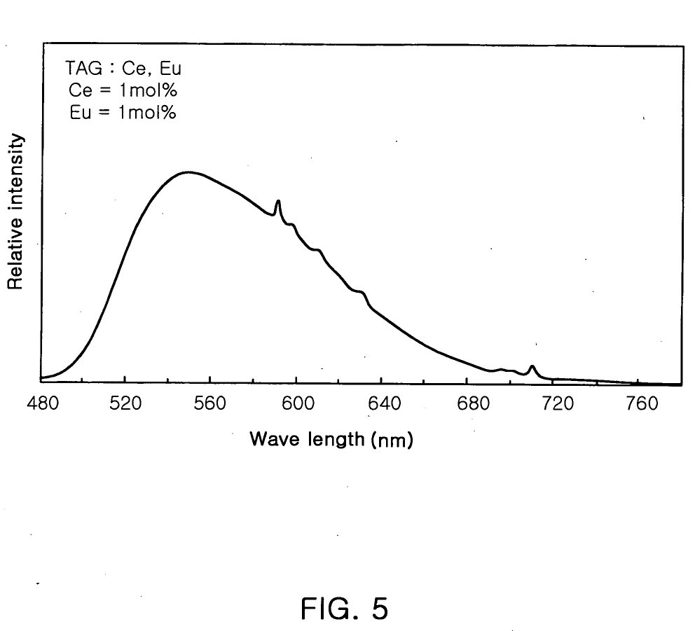

FIGS. 2 to 5 show the light emission spectra of TAG:Ce,Eu phosphors containing 1 mol % of Ce activator. In particular, to confirm its applicability to a blue LED, the light emission spectra of the phosphors are obtained using excitation light of 460 nm.

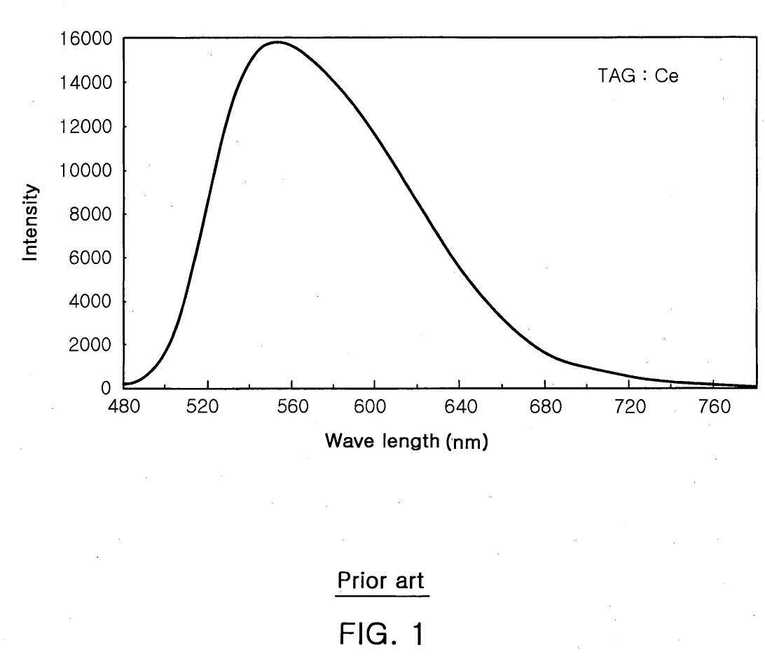

First, FIG. 2 shows the light emission spectrum of TAG:Ce,Eu phosphor containing 7 mol % of Eu co-activator. Referring to FIG. 2, unlike the conventional TAG:Ce phosphor illustrated in FIG. 1, light emission peaks are formed in the red wavelength region due to the Eu co-activator. That is, the light emission spectrum in FIG. 2 (the spectrum of TAG:Ce,Eu) has a form in which the Eu light emission peaks are added to the spectrum (dotted line) of the conventional TAG:Ce. The light emission peaks due to Eu are formed at about 591 nm, 597 nm, 610 nm, 631 nm, 696 nm and 710 nm. The Eu light emission peaks formed at the Eu light emission wavelengths (the wavelengths at which the Eu light emission peaks are formed) function to reinforce the red region of the yellow phosphor.

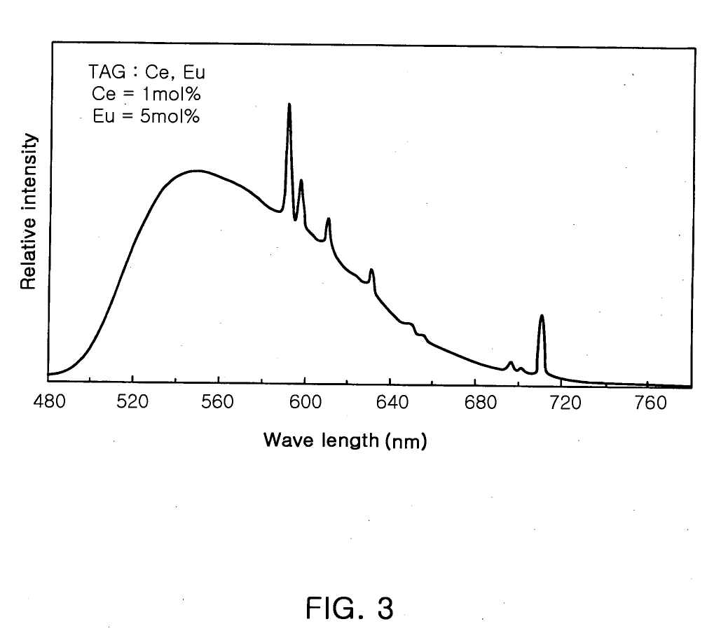

FIGS. 3 to 5 are light emission spectra of TAG:Ce,Eu phosphors containing 5 mol %, 3 mol % and 1 mol % of the Eu co-activator, respectively. As shown in FIGS. 3 to 5, in spite of the differing contents of Eu co-activator, the Eu light emission wavelengths do not differ. Therefore, similar to the previous embodiment, in the embodiments shown in FIGS. 3 to 5, the light emission peaks of Eu are formed at about 591 nm, 597 nm, 610 nm, 631 nm, 696 nm and 710 nm, reinforcing the red wavelength region.

As shown in FIGS. 2 to 5, in the case where the content of the Ce activator is fixed (particularly, where the content of Ce is fixed at 1 mol %), the light emission intensity of Eu becomes decreased with the smaller content of the Eu co-activator. Therefore, especially the case in FIG. 2 (where Ce is 1 mol % and Eu is 7 mol %), out of the cases of FIGS. 2 to 5, yields the greatest reinforcement effect of the red region due to Eu.

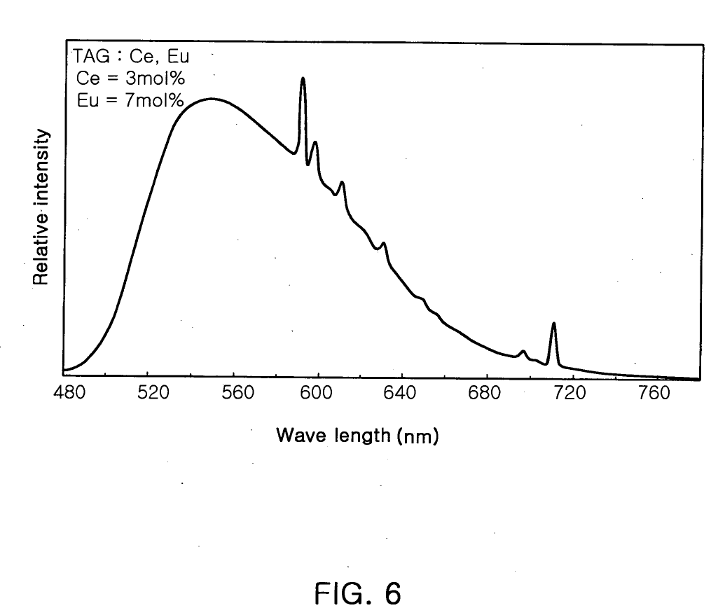

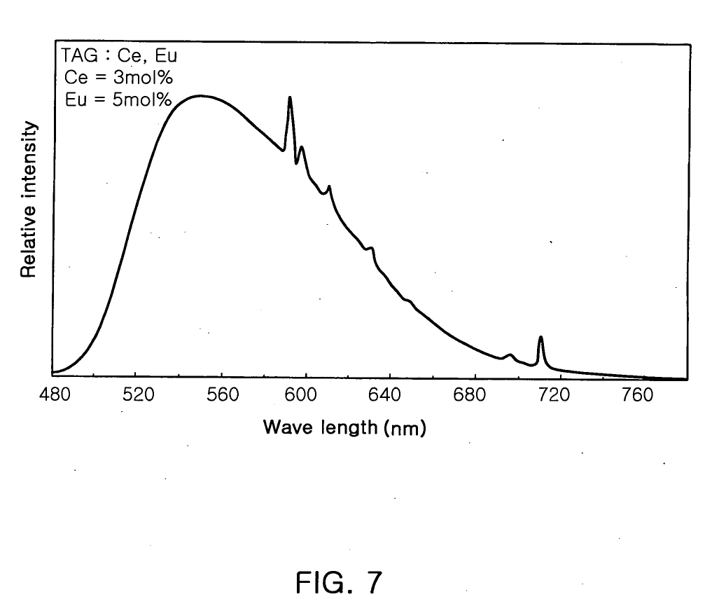

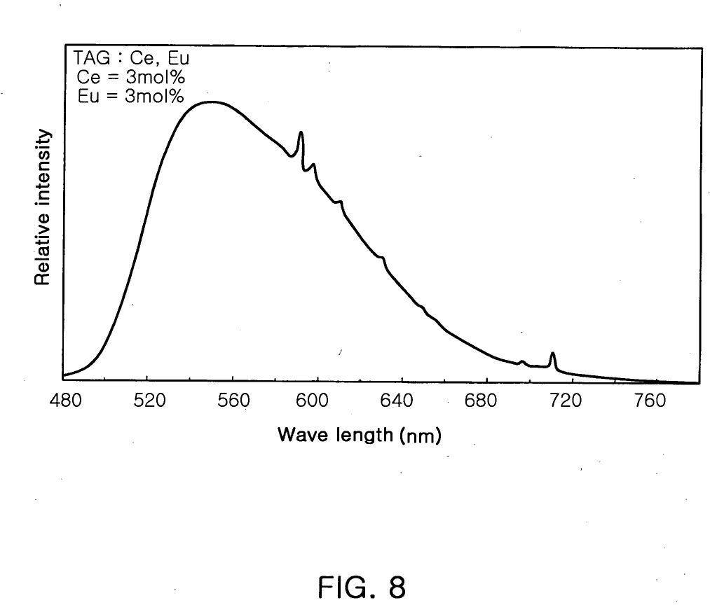

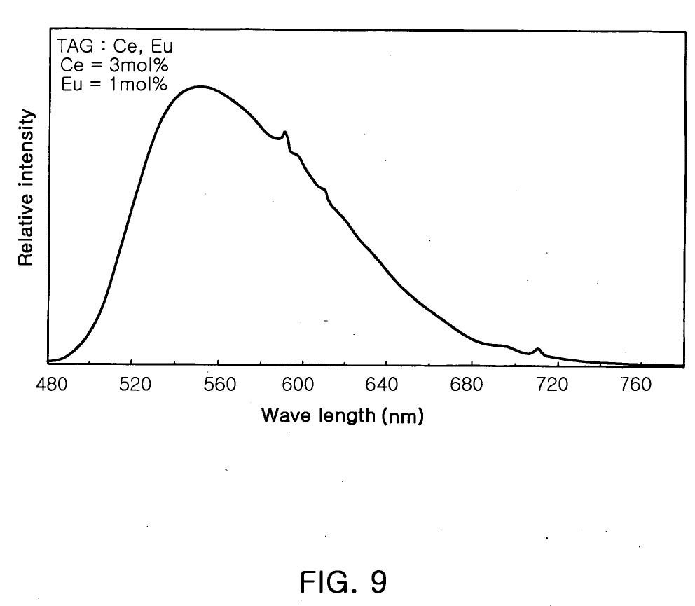

FIGS. 6 to 9 are light emission spectra of TAG:Ce,Eu phosphors containing 3 mol % of the Ce activator. In particular, FIGS. 6 to 9 are the light emission spectra of TAG:Ce,Eu phosphors containing, 7 mol %, 5 mol %, 3 mol % and 1 mol % of Eu, respectively. Similar to the previous embodiments, in the embodiments illustrated in FIGS. 6 to 9, the Eu light emission peaks are formed in the red wavelength region. Similar to FIGS. 2 to 5, the Eu light emission peaks are formed at about 591 nm, 597 nm, 610 nm, 631 nm, 696 nm and 710 nm in FIGS. 6 to 9. Similar to the previous embodiments, in the case where the content of Ce is fixed (particularly, the content of Ce is 3 mol %), the Eu light emission wavelength intensity decreases with smaller content of Eu.

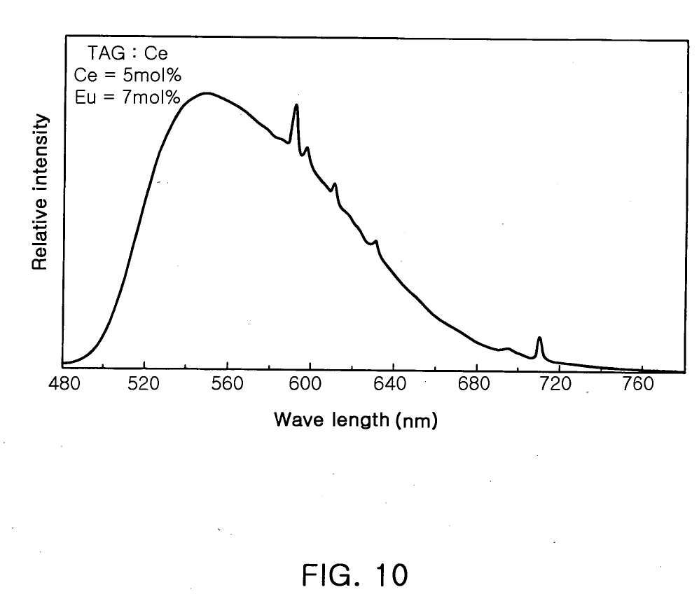

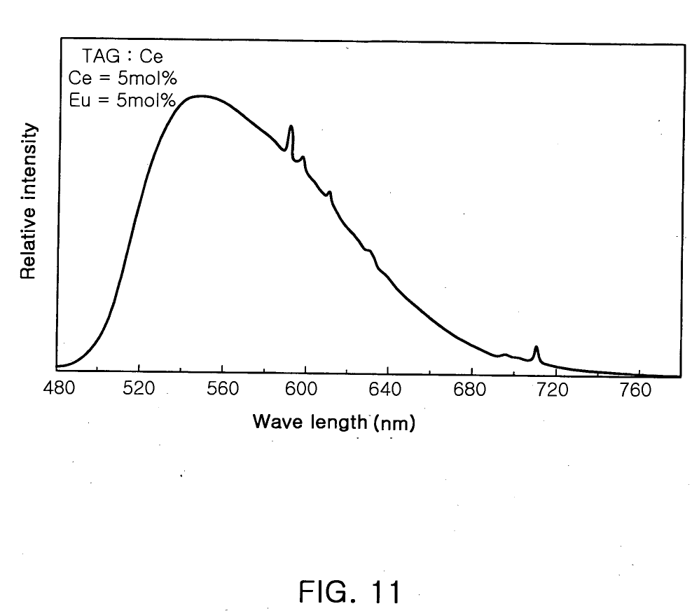

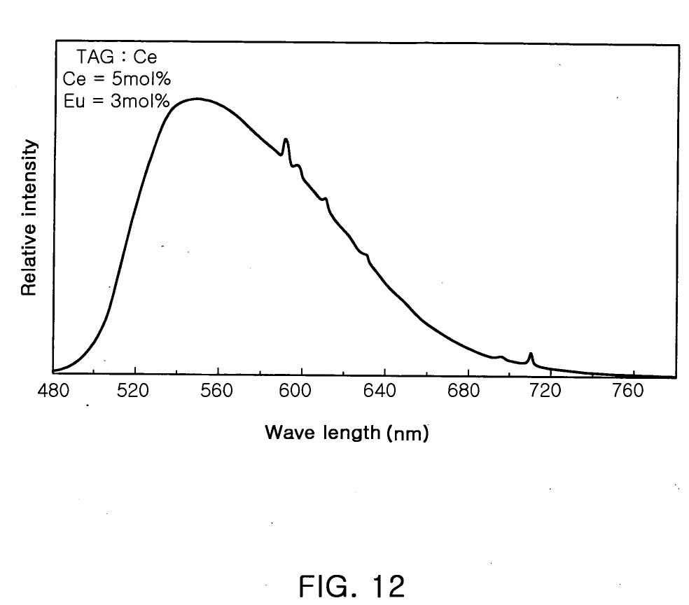

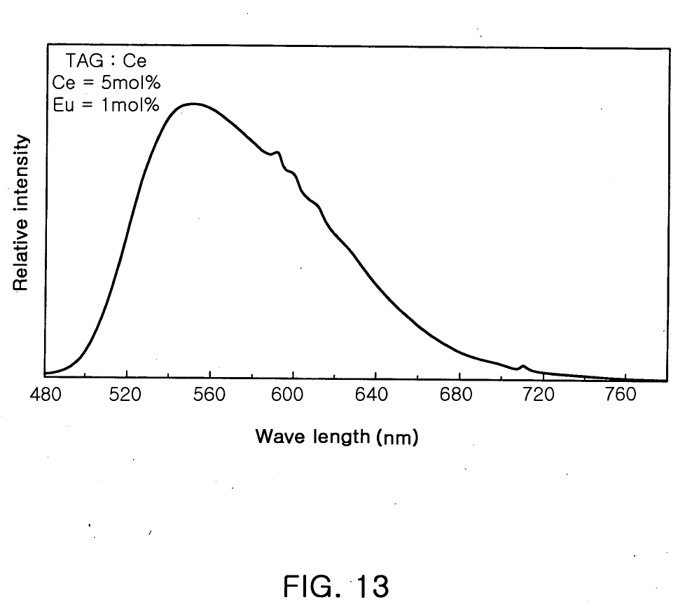

FIGS. 10 to 13 are light emission spectra of TAG:Ce,Eu phosphors containing 5 mol % of the Ce activator. In particular, FIGS. 10 to 11 are light emission spectra of TAG:Ce,Eu phosphors containing 7 mol %, 5 mol %, 3 mol % and 1 mol % of Eu, respectively. As shown in FIGS. 10 to 13, in the case where the content of Ce is fixed (particularly, the content of Ce is 5 mol %), the Eu light emission wavelength intensity decreases with smaller content of Eu.

Comparing the light emission spectra of FIGS. 2 to 5 (where the content of Ce is 1 mol %), the light emission spectra of FIGS. 6 to 9 (where the content of Ce is 3 mol %), and the light emission spectra of FIGS. 10 to 13 (where the content of Ce is 5 mol %), it can be seen that when the Eu co-activator is added to the yellow phosphor TAG:Ce, the Eu light emission peaks are formed at specific wavelength values (591 nm, 597 nm, 610 nm, 631 nm, 696 nm and 710 nm).

In addition, in the case where the content of Ce is fixed, the Eu light emission wavelength intensity increases with greater content of Eu. That is, as the content of Eu increases, the effect of reinforcing the red wavelength region is increased as well. In addition, as the content of Ce is increased, the relative intensity of the Eu light emission wavelength due to the Eu co-activator (the relative intensity of the Eu light emission wavelength with respect to the total intensity of TAG:Ce,Eu phosphor) decreases, resulting in declining reinforcement effect of the red region. Therefore, the contents of Ce and Eu are adjusted in the TAG:Ce,Eu phosphor to thereby suitably reinforce the red wavelength region, thus achieving optimal color reproducibility.

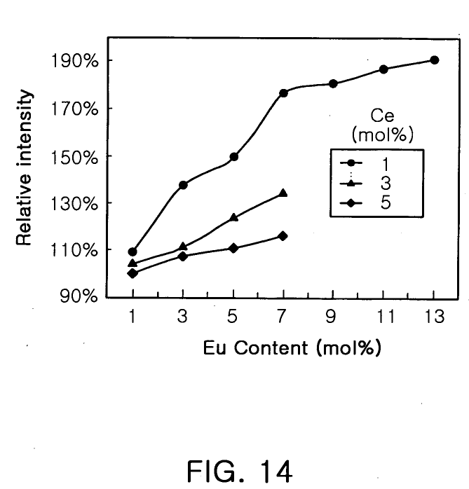

FIG. 14 is a graph showing the relative light emission intensity of the TAG:Ce,Eu phosphor with respect to that of the TAG:Ce phosphor. In particular, FIG. 14 shows the change in the relative intensity of the TAG:Ce,Eu phosphor according to the contents of Ce and Eu (the relative light emission intensity of TAG:Ce,Eu with respect to TAG:Ce).

Referring to FIG. 14, given the same content of Ce, as the content of Eu is increased, the relative intensity of Eu light emission wavelength of the TAG:Ce,Eu phosphor (i.e., the degree of reinforcement of the red wavelength region) increases. For example, when the content of Ce is fixed at 3 mol %, the relative intensity (with respect to TAG:Ce) of the Eu light emission wavelength at 3 mol % of Eu is about 10%, and at 5 mol % of Eu is about 25%.

In addition, as the content of the Ce activator increases, the relative intensity of the Eu light emission wavelength of the TAG:Ce,Eu phosphor (i.e., the degree of reinforcement of the red wavelength region) decreases. For example, when the content of Eu is 5 mol %, the Eu light emission wavelength at 1 mol % of Ce is about 50%, and at 5 mol % of Ce is about 10%. This is because, as the content of Ce increases, the actual intensity of the Ce activator is relatively greater than the actual intensity of the Eu light emission wavelength.

Therefore, by increasing the content of Eu and/or decreasing the content of Ce, the relative intensity of the Eu light emission wavelength (i.e., the degree of the reinforcement of the red wavelength region) can be increased. Conversely, by decreasing the content of Eu and/or increasing the content of Ce, the relative intensity of the Eu light emission wavelength (i.e., the degree of the reinforcement of the red wavelength region) can be decreased. Therefore, according to the present invention, the contents of the Ce activator and the Eu co-activator are suitably adjusted to control the degree of reinforcement of the red wavelength region in order to obtain the optimal color reproducibility. In particular, to sufficiently reinforce the red wavelength region while maintaining the yellow-phosphor characteristics, the preferable content of Ce is 1 mol % to 30 mol %, and the preferable content of Eu is 1 mol % to 30 mol %.

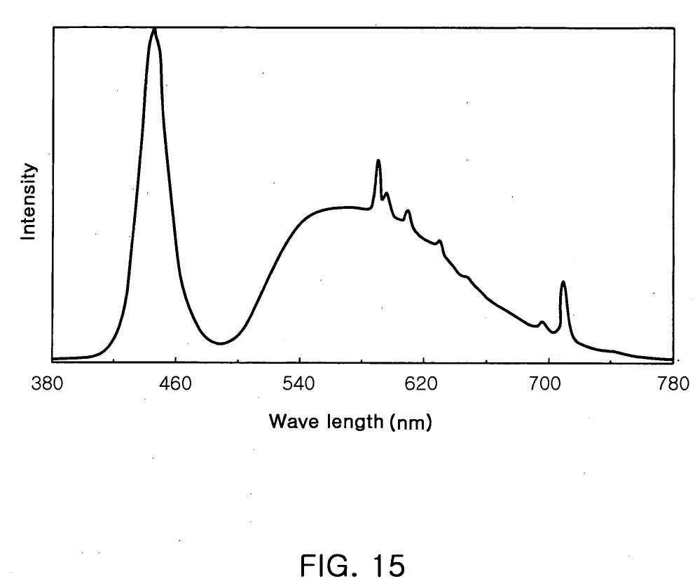

FIG. 15 shows the light emission spectrum of a white light emitting device in which the yellow phosphor TAG:Ce,Eu is applied to a blue LED. To obtain the light emission spectrum of FIG. 15, an encapsulant with the TAG:Ce,Eu phosphor dispersed therein is applied onto a GaN-based blue LED. The light emission peak exhibited in the left part of the spectrum of FIG. 15 represents the light emission peak of blue light emitted from the LED chip. As shown in FIG. 15, even in the case where the TAG:Ce,Eu is applied to the blue LED, similar to the light emission spectrum of TAG:Ce,Eu itself (see FIGS. 2 to 13), the Eu light emission peaks are observed at about 591 nm, 597 nm, 610 nm, 631 nm, 696 nm and 710 nm in the red wavelength region. Therefore, the TAG:Ce,Eu phosphor can be used in the white light emitting device as described above to obtain an improved light emission spectrum in the red wavelength region.

In order to manufacture the TAG:Ce,Eu phosphor, a solid phase method can be used. Specifically, Tb₄O₇ is used as material for Terbium (Tb), Al₂O₃ as material for aluminum, CeO₂ as material for cerium and Eu₂O₃ can be used as material for europium. Alternatively, nitrides, chlorides, sulfides or hydroxides can be used as materials for the respective elements, instead of oxides. For flux, BaF₂, LiF or H₃BO₃ can be used. The material and flux are dispersed in alcohol and hydrate, and the dispersion is churned to obtain a suitably mixed mixture. Then, the alcohol and the hydrate in the mixture are evaporated, and the resultant product is heated in H₂ and N₂ gas atmosphere at a high temperature ranging from 1000 to 1700° C. for a predetermined time to reduce the resultant product. Thereby, the TAG:Ce,Eu phosphor is obtained.

In the previous embodiments, only the TAG:Ce,Eu was mentioned as the yellow phosphor, but does not limit the present invention. YAG:Ce,Eu yellow phosphor can also be used to yield the reinforcement effect of the red wavelength region due to the Eu co-activator. According to the present invention, to obtain the reinforcement effect of the red wavelength region, yellow phosphor having a formula, Mₓ(Al, Ga)₅O₁₂:Ce_{y},Eu_{z} (where M is at least one selected from a group consisting of Tb, Y, Gd, La and Sm, and where 2.4≦x≦2.998, 0.001≦y≦0.3 and 0.001≦z≦0.3) can be used. Such phosphor is applied to the blue light source (particularly, a blue LED), thereby realizing a white light emitting device having superior light emission characteristics.

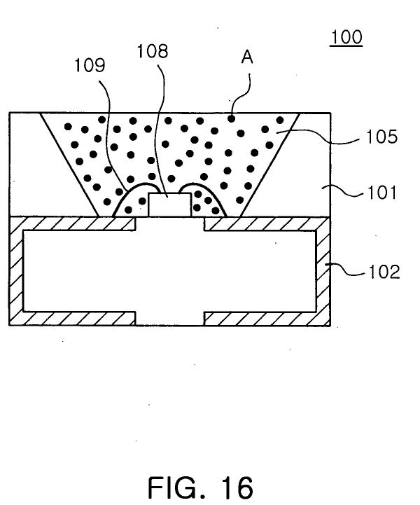

FIG. 16 is a sectional view illustrating a white light emitting device according to an embodiment of the present invention. Referring to FIG. 16, the light emitting device 100 has a blue LED 108 disposed in a recessed part of a casing 101. A gallium nitride-based LED emitting blue light of 420 to 480 nm can be used for the blue LED 108. A side surface of the casing 101 forms a reflecting surface. Terminal electrodes 102 disposed inside the casing 101 are connected to the blue LED 108 by bonding wires 109. An encapsulant is formed on the LED 108 to encapsulate the LED 108. For the encapsulant, an epoxy resin, a silicone resin or a hybrid resin of epoxy and silicone can be used.

In the encapsulant 105, yellow phosphor A (sufficiently reinforced in its red wavelength region) according to the present invention is dispersed. For example, TAG:Ce,Eu can be used for the yellow phosphor A. Applying the yellow phosphor according to the present invention to the blue LED, the conventionally weak red wavelength region is reinforced. As a result, the white light emitting device 100 has improved color rendering index and color reproducibility.

In the embodiment shown in FIG. 16, the blue LED is used for the blue light source, but does not limit the present invention. Besides the blue LED, for example, a blue light emission lamp can be used.

The yellow phosphor according to the present invention set forth above allows a light emission spectrum with a red wavelength region suitably reinforced. Therefore, the yellow phosphor can be used to realize a white light emitting device having superior color rendering index and color reproducibility.

While the present invention has been shown and described in connection with the preferred embodiments, it will be apparent to those skilled in the art that modifications and variations can be made without departing from the spirit and scope of the invention as defined by the appended claims.

What is claimed is:

1. Yellow phosphor having a composition expressed by a formula of Mₓ(Al, Ga)₅O₁₂:Ce_{y},Eu_{z}, wherein M is at least one selected from a group consisting of Tb, Y, Gd, La and Sm, where 2.4≦x≦2.998, 0.001≦y≦0.3 and 0.001≦z≦0.3.

2. The yellow phosphor according to claim 1, wherein the formula comprises TAG:Ce,Eu.

3. The yellow phosphor according to claim 2, comprising 1 to 10 mol % of Ce.

4. The yellow phosphor according to claim 3, comprising 1 to 10 mol % of Eu.

5. The yellow phosphor according to claim 1, comprising YAG:Ce,Eu.

6. A white light emitting device comprising:
a blue light source; and
yellow phosphor dispersed on the blue light source, the yellow phosphor having a composition expressed by a formula of Mₓ(Al, Ga)₅O₁₂:Ce_{y},Eu_{z}, wherein M is at least one selected from a group consisting of Tb, Y, Gd, La and Sm, where 2.4≦x≦2.998, 0.001≦y≦0.3 and 0.001≦z≦0.3.

7. The white light emitting device according to claim 6, wherein the yellow phosphor has a formula of TAG:Ce,Eu.

8. The white light emitting device according to claim 6, wherein the yellow phosphor has a formula of YAG:Ce,Eu.

9. The white light emitting device according to claim 6, wherein the blue light source comprises a blue light emitting diode.

10. The white light emitting device according to claim 9, wherein the blue light emitting diode has a peak light emission wavelength ranging from 420 to 480 nm.

11. The white light emitting device according to claim 9, further comprising an encapsulant formed on the blue light emitting diode, the encapsulant having the yellow phosphor dispersed therein.

12. The white light emitting device according to claim 11, wherein the encapsulant is made of one selected from a group consisting of an epoxy resin, a silicone resin and a hybrid resin of epoxy and silicone.
